(19) United States
(12) Patent Application Publication
(10) Pub. No.: US 2013/0342078 A1
(43) Pub. Date: Dec. 26, 2013

(54) APPARATUS AND METHOD OF MAKING A MULTI-LAYERED PIEZOELECTRIC ACTUATOR

(71) Applicant: U.S. Army Research Laboratory ATTN: RDRL-LOC-I, Adelphi, MD (US)

(72) Inventor: Leonid A. Beresnev, Columbia, MD (US)

(73) Assignee: U.S. Army Research Laboratory ATTN: RDRL-LOC-I, Adelphi, MD (US)

(21) Appl. No.: 14/010,568

(22) Filed: Aug. 27, 2013

Related U.S. Application Data
(60) Provisional application No. 61/709,195, filed on Oct. 3, 2012.

(51) Int. Cl. H01L 41/09; H01L 41/27

(52) U.S. Cl. CPC H01L 41/0926; H01L 41/27
USPC 310/331; 29/25.35

(57) ABSTRACT

A method and apparatus for a layered piezoelectric actuator comprising: a first conductive layer and second conductive layer disposed on a first piezoelectric layer. The apparatus further comprising a third conductive layer and fourth conductive layer disposed on a second piezoelectric layer. Further, adhesive is disposed between the second conductive layer and third conductive layer, wherein the conductive layers further comprise a bending area and non-bending area. The non-bending area comprises the mounting area and connection area The connection area further comprises the connection points, opening to access the connection point of adjacent layer and overlap area, providing the stability/robustness of stack during the fabrication, adhering and exploitation of the bending actuator. The conductive layers in non-bending areas have offset conductive stripes without electrical activation of piezoelectric material in non-bending area

### CROSS REFERENCE TO RELATED APPLICATIONS

This application claims benefit of U.S. provisional patent application Ser. No. 61/709,195, filed Oct. 3, 2012, which is herein incorporated by reference.

### GOVERNMENT INTEREST

Governmental Interest—The invention described herein may be manufactured, used and licensed by or for the U.S. Government.

### FIELD OF INVENTION

Embodiments of the present invention generally relate to piezoelectric actuators and, more particularly, to an apparatus and method of making a multi-layered piezoelectric actuator.

### BACKGROUND OF THE INVENTION

The piezoelectric effect is the linear electromechanical interaction between the mechanical and the electrical state in crystalline materials with no inversion symmetry. Typically, ceramic piezoelectric material is placed between two conductive layers capable of transmitting or receiving a voltage bias via the piezoelectric material. The bias of the applied voltage results in a contraction or expansion of the piezoelectric material which translates into a bi-directional mechanical movement of the piezoelectric material. Various structures have been developed in the field of piezoelectric actuators to increase the overall efficiency of converting electrical energy into mechanical movement and vice versa.

Conventional structures stack symmetrically shaped piezoelectric plates and conductors to form a bimorph actuator. The piezoelectric plates are separated by a metal shim to increase stiffness between layers as well as serve as a common electrode. The metal shims are adhered to the piezoelectric plates by conductive glue. However, the shims and glue adds interlayer thickness and reduces the overall actuator sensitivity (e.g. amplitude of bending versus a unit of applied voltage), Uneven glue distribution during the manufacture of the bimorph actuator also attributes to parasitic capacitance and decreases the usable lifetime of the actuator, In addition, non-bending areas add parasitic capacitance as well as cause structural stress during prolonged and/or high frequency applications (e.g. 1-100 kHz). Other technologies such as MEMs or chemical etching may be applied to piezoelectric actuator fabrication to overcome such difficulties but are very expensive.

Therefore, a need exists for a cost effective, piezoelectric actuator capable of operating at high frequencies, and fabrication technique thereof.

### BRIEF SUMMARY OF THE INVENTION

Embodiments of the present invention comprise in some embodiments an apparatus for a layered piezoelectric actuator. The actuator comprising a first conductive layer and second conductive layer disposed on a first piezoelectric layer. The apparatus further comprising a third conductive layer and fourth conductive layer disposed on a second piezoelectric layer. Further, adhesive is disposed between the second conductive layer and third conductive layer, wherein the conductive layers further comprise an oscillating bending area and a stationary non-bending area, and wherein the stationary non-bending area further comprises a mount area and a connection area.

In some embodiments, a method for fabricating a layered piezoelectric actuator comprises depositing a first conductive layer and second conductive layer on a first piezoelectric layer. Furthermore, depositing a third conductive layer and fourth conductive layer on a second piezoelectric layer. Further, the method comprises thinning a portion of the conductive layers to form a continuous conductive strip from each conductive layer. Lastly, depositing adhesive between the second conductive layer and third conductive layer, wherein the conductive layers further comprise an oscillating bending area and a stationary non-bending area, and wherein the stationary non-bending area further comprises a mount area and a connection area.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1A is an illustration of a top and bottom view of a first piezoelectric layer in accordance with one embodiment of the invention.

FIG. 1B is an illustration of a top and bottom view of a second piezoelectric layer in accordance with one embodiment of the invention,

FIG. 2 is an illustration of an isometric view of an assembled bimorph piezoelectric actuator in accordance with one embodiment of the invention.

FIG. 3 is an illustration of a side view of the assembled bimorph piezoelectric actuator of FIG. 2.

FIG. 4 is an illustration of a cutaway side view of multiple four layer piezoelectric actuators during fabrication between pressure plates in accordance with one embodiment of the invention.

FIG. 5 is an illustration of the pressure plates in accordance with one embodiment of the invention, as applied in FIG. 4.

FIG. 6 is an illustration of a top view of the actuators during fabrication between the stacked pressure plates of FIGS. 4 and 5, in accordance with one embodiment of the invention.

FIG. 7 is an illustration of a temporary mounting assembly for final cut of the actuators during fabrication in accordance with one embodiment of the invention.

FIG. 8 is a flow diagram of an exemplary method for fabricating the multilayered piezoelectric actuator in accordance with one embodiment of the invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION OF THE INVENTION

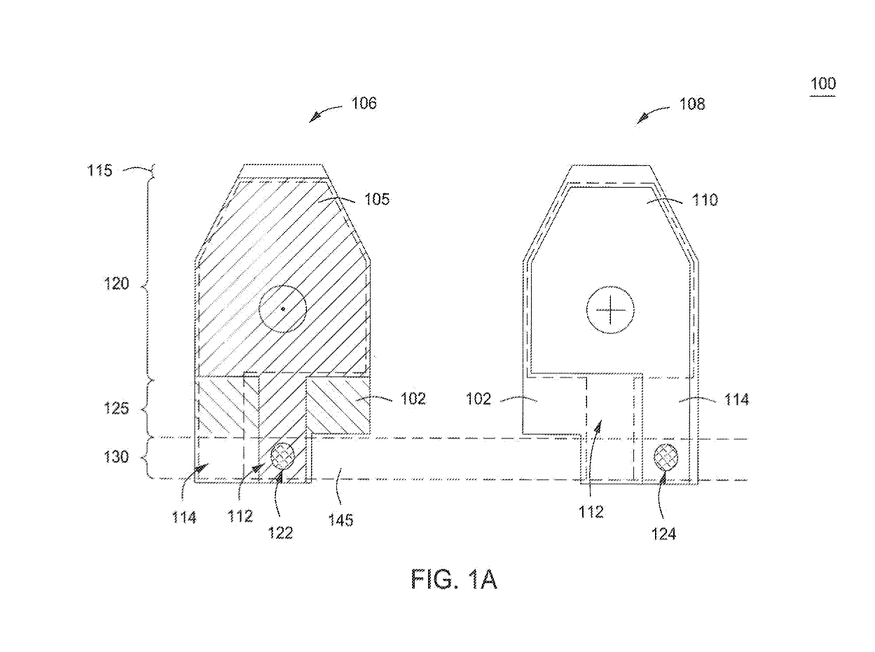

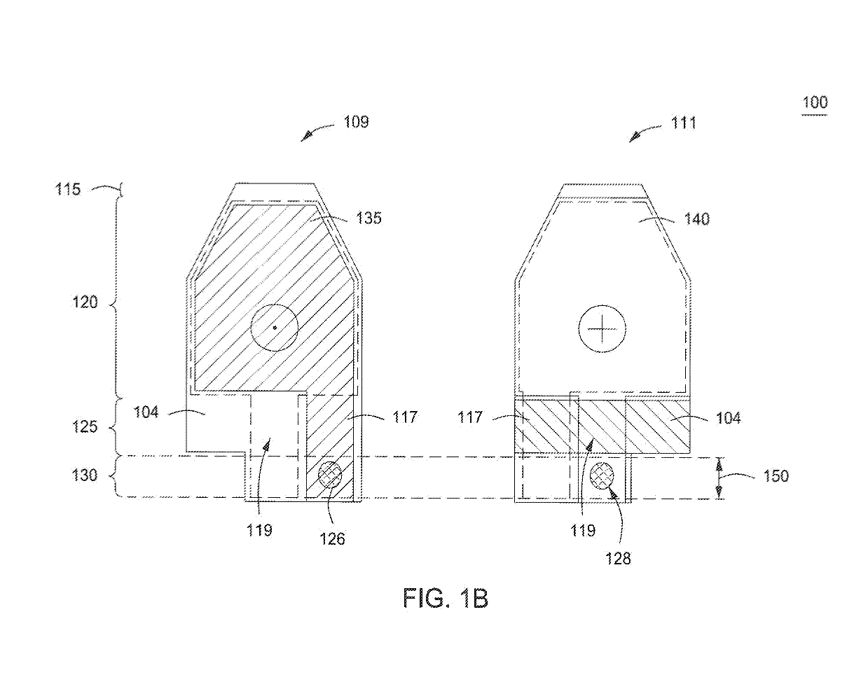

FIG. 1A is an illustration of a first piezoelectric layer or plate 102 from a top and bottom view (106, 108) in accordance with one embodiment of the invention. The first piezoelectric layer 102 is stacked onto a second piezoelectric layer 104 to form a piezoelectric bimorph actuator 100. The first piezoelectric layer 102 comprises an area 115 for a load (not shown), a bending area 120, a mounting area 125, a connection area 130, a first conductive layer 105, and a second conductive layer 110. The area 115 for the load (not shown) and bending area 120 are shaped to remove orthogonal edges to reduce excessive piezoelectric material. At higher mechanical frequencies (kHz, MHz, and the Is like), minimizing the contact point (area for the load 115) results in increased bending wave propagation. The large size of the bending area 120 is correlated with a reduction of an inertial moment and reduces the operating frequency bandwidth of the actuator 100. Thus, a reduction in the size of the bending area 120 and area 115 for mounting the load increases efficiency of bending wave propagation to the load.

The top view 106 illustrates that the first conducting layer 105 substantially mimics the shape of the underlying first piezoelectric layer 102. The first conducting layer 105 is disposed or etched such that it does not overlap the area 115 for the load. The first conducting layer 105 is located at the bending area 120 and tapered at the opposite distal end of the area 115 for the load. The tapering forms a first conductive strip 112. The first conductive strip 112 is continuous from the mounting area 125 to the connection area 130.

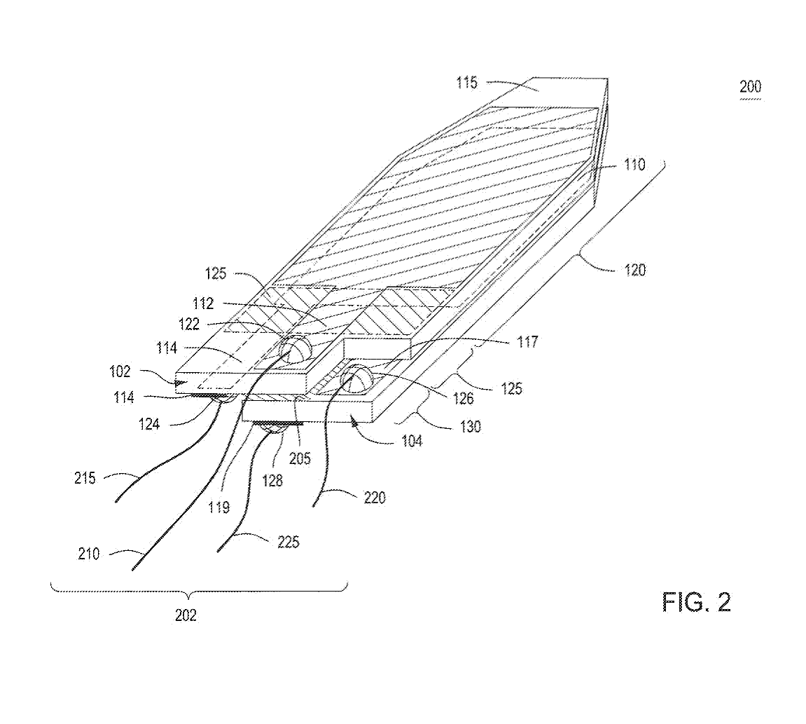

The conductive strip 112 is horizontally offset from a second conductive strip 114 formed by tapering in the second conductive layer 110 located on the underside of the first piezoelectric layer 102. The first and second conductive strips (112 and 114) are decoupled by not directly overlapping the first piezoelectric layer 102. As such, the piezoelectric material therebetween is not energized when a voltage bias is placed across the strips (112, 114). Thus, mechanical stress is avoided in the mounting and connection areas (125 and 130) as the areas are non-bending and stationary. At the distal end from the bending area 120 on the first conductive strip 112 is a first connection point 122. The first connection point 122 allows for connection to external circuitry (e.g. via soldering at connection point 122 to wires). An opening 145 is formed in the first piezoelectric layer 102 to allow access to additional connection points, e.g. a third connection point 126, of subsequently stacked piezoelectric layers, as will be described in greater detail in relation to FIG. 2. The opening 145 is of a sufficient width 150 to allow for access to the underlying connection points, e.g. the third connection point 126. The opening 145 facilitates connection to the piezoelectric layers after their assembly in to a bimorph piezoelectric actuator.

The bottom view 108 depicts the second conductive layer 110 on the underside of the first piezoelectric layer 102. The second conductive layer 110 is of substantially the same shape in the bending area 120 as that of the first conductive layer 105. The second conductive layer 110 has a second conductive strip 114 with a second connection point 124, As noted above, the second conductive strip 114 is horizontally offset from the first conductive strip 112 such that there is substantially reduced or no capacitive coupling across the first piezoelectric layer 102. Without the capacitive coupling, the piezoelectric material in the mounting and connection areas (125 and 130) is not energized and does not oscillate. Thus mechanical stress is reduced and protects the connection points (122 and 124) from deterioration during operation, as well as protects the mounting area 130 from deterioration of adhesive (e.g., glue) used to attach the actuator to the mount. The reduction in capacitive coupling also allows for decreased parasitic capacitance.

FIG. 1B is an illustration of a second piezoelectric layer from a top 109 and bottom 111 view in accordance with one embodiment of the invention. Similar to the first piezoelectric layer 102, the second piezoelectric layer 104 is sandwiched between a third conductive layer 135 disposed opposite a fourth conductive layer 140, so as to form bending area 120. The third conductive layer 135 is tapered or thinned to form a third conductive strip 117 and establish thereon a third connection point 126. After stacking of the first and second piezoelectric layers as shown in FIG. 1B, the third connection point 126 is able to be accessed via the opening 145 formed in the first piezoelectric layer 102. In some embodiments, the opening 145 is similarly formed in the second piezoelectric layer 104 for additional access via the underlying piezoelectric layer 104. The fourth conductive layer 140 is tapered to form a fourth conductive strip 119 with a fourth connection point 128. The third and fourth conductive strips (117 and 119) are horizontally offset in the same manner as the first and second conductive strips (112 and 114) such that there is no capacitive coupling,

As a non-limiting example, in some embodiments, the conductive layers (105, 110, 135, 140) comprises a metal film (e.g. Nickel), deposited onto the piezoelectric layers using photolithography.

FIG. 2 is an isometric view illustration of an assembled bimorph piezoelectric actuator 200 in accordance with one embodiment of the invention. The actuator 200 comprises the first piezoelectric layer 102 adhered using an adhesive. The embodiments herein disclose an adhesive as a glue (conductive or non conductive) in a glued area 205, however, additional embodiments may include other forms of flexible bonding agents to adhere layers such as ultrasonic welding, thermoplastic, epoxy, UV cured glues, thermoplastics, waxes, hard setting liquid resin, and the like. The actuator 200 further comprises the second piezoelectric layer 104 coupled to wires 202.

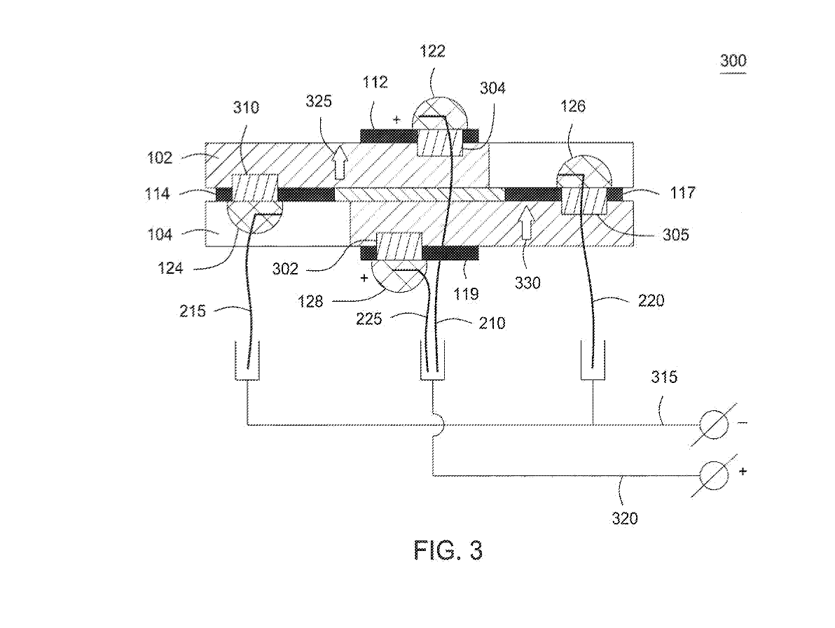

The glued area 205 adheres the second conducting area 110, first conductive strip 114, and first piezoelectric layer 102 to the third conducting area 135 (not shown in FIG. 2), the third conducting strip 117, and the second piezoelectric layer 104. The first conducting strip 112 further comprises the first connection point 122 coupled to a first wire 210. The second conductive strip 114 comprises the second connection point 124 coupled to a second wire 215. The third conductive strip 117 comprises the third connection point 126 coupled to a third wire 220. The fourth conductive strip 119 comprises the fourth connection point 128 coupled to a fourth wire 225. As will be discussed with respect to FIG. 3, conductive glue may be used in the glued area 205 to form a common electrode with the second and third conductive strips (114, 117), since the second and third conductive strips (114, 117) are of the same polarity. However, according to some (embodiments, the electric voltage can be delivered to the second and third conductive areas (110, 135) through the wires (215, 220) and conductive stripes (114, 117), substantially increasing a glue choice favoring fluidity over conductivity for glue in area 205 since fluidity in the glue allows for improved oscillation of the actuator 200. Similarly, oscillation is improved since less residual glue remains in between piezoelectric plates after squeezing.

FIG. 3 is an illustration of a side view of an assembled bimorph piezoelectric actuator 300 of FIG. 2 in accordance with one embodiment of the invention. The assembled piezoelectric actuator 300 comprises a first lead wire 210, a second lead wire 215, a third lead wire 220, and fourth lead wire 225. The second and third lead wires (215, 220) are coupled to a first source wire 315 of negative polarity. The first and fourth lead wires (210, 225) are coupled to a second source wire 320 of positive polarity. Each piezoelectric layer (102 and 104) is thus coupled to a wire of opposite polarity so as to produce a voltage bias across each piezoelectric layer (102,104). The shown set of polarities of electric voltage realizes the basic requirement to activate the bending of bimorph actuator 300. Namely, the polarity of electric field in piezoelectric layer 102 is directed opposite to a first spontaneous polarization (represented as arrow 325), activating the longitudinal contraction of layer 102. The polarity of electric voltage in piezoelectric layer 104 is directed along a second spontaneous polarization (arrow 330), activating the longitudinal expansion of layer 104. As a result, the stack of two layers (102, 104) is activated and bends such that the loading area 115 is moving upwards (FIG. 2).

Connection points (122, 124, 126, 128) may be formed using solder and lead wires (210, 215, 220, 225). In some embodiments, the solder may form a more secure connection when a channel or well (302, 304, 305, 310) is etched into the one of the piezoelectric substrates (102 or 104) and corresponding conductive strip (112, 114, 117, 119). The wells (302, 304, 305, 310) provide a greater surface area to form the connection points (122, 124, 126, 128).

Piezoelectric layers are extremely fragile and as well require careful manufacturing techniques to prevent contamination of the piezoelectric layers by the glue/liquid adhesive that is used to adhere the layers together, and at the same time, prevent breakage while providing connections to the conductive layers. Specific areas such as mounting and connection areas (125,130) overlap for stability, stiffness, robustness and remain stationary. The greater the distance between the oscillating areas (e.g., loading area 115 and bending area 120) and the connection point (e.g., 122) reinforces against occasional non-uniformity of pressure or viscosity of the liquid adhesive. Thus increasing the size of the non-bending areas also increases the protection of fragile connection points (e.g. 122, 124) from unintentional movement from the oscillating areas (e.g., 115, 120).

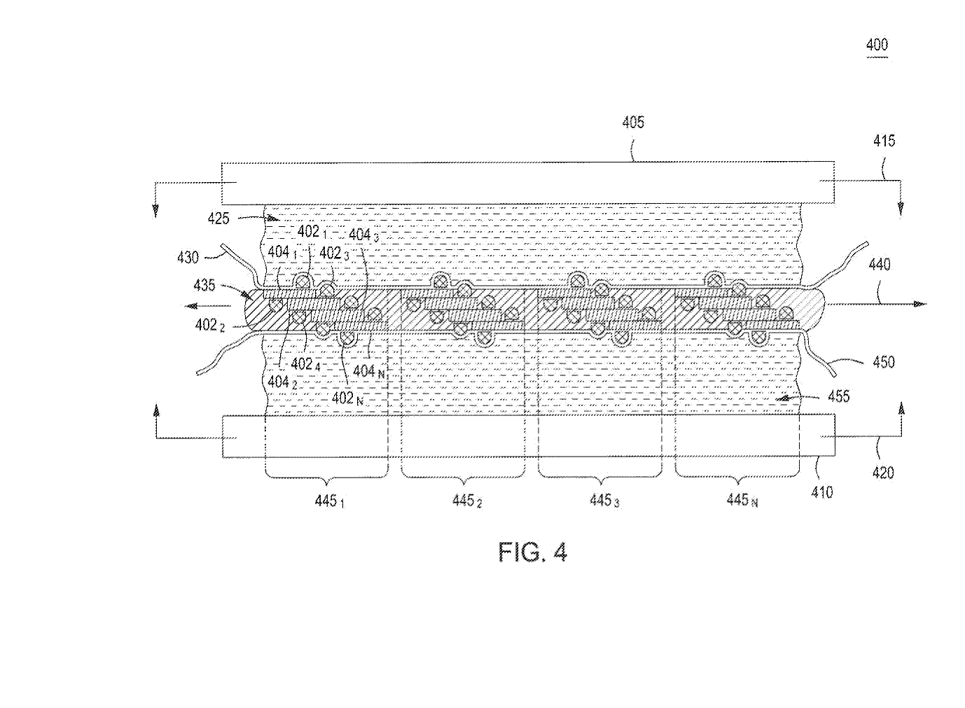

Accordingly, FIG. 4 is an illustration of a cutaway view of multiple four layer piezoelectric actuators (445₁, 445₂, 445₃, 445_{N}) during fabrication between pressure plates (405, 410) in accordance with another embodiment of the invention. The piezoelectric actuators (445₁, 445₂, 445₃, 445_{N}) are of substantially similar structure as those shown and described in conjunction with FIGS. 1-3, however each comprises four or six or even more piezoelectric layers instead of two. The use of additional piezoelectric layers increases the frequency bandwidth of the actuator without the need to increase the voltage bias. Each piezoelectric actuator (445₁, 445₂, 445₃, 445_{N}) comprises piezoelectric layers (404₁, 404₂, 404₃, . . . 404_{N}) with corresponding connection points (402₁, 402₂, 402₃, . . . 402_{N} and corresponding metal films (not shown).

A press 400 comprises a first pressure plate 405, a first elastic material 425, a first thin film 430, adhesive 435, the piezoelectric actuators 445, a second thin film 450, a second elastic material 455, and a second pressure plate 410. The first and second elastic material (425, 455) comprising attributes of low hardness and compression (e.g. silicon based foam). The thin films (430, 450) comprise low adhesion thin disposed on the elastic material (425, 455) to allow release from the adhesive 435 after the adhesive 435 sets. In some embodiments, the first and second pressure plates (405, 410) are comprised of metal (iron, steel, aluminum, and the like).

Equal pressure forces (415, 420) combine to form a bi-directional sandwich pressure against the aforementioned materials in the press 400. In some embodiments, the upward force 420 may be the opposing force of the applied downward force 415, Excess liquid adhesive is squeezed away from the center of the press 400 and the piezoelectric actuators 445. Once the excess adhesive is squeezed out, the adhesive may be removed from the sides of the thin films (430, 450).

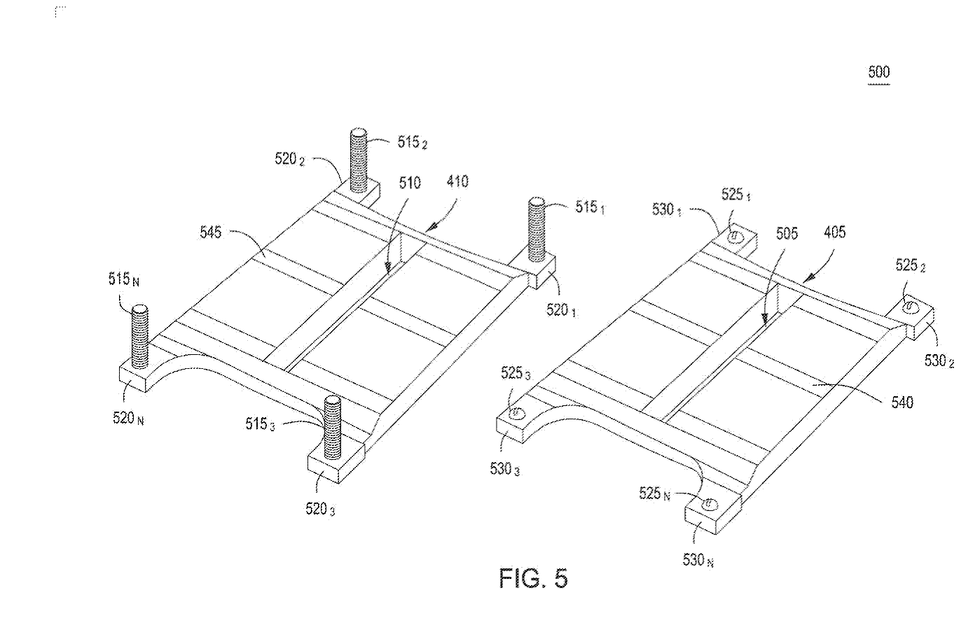

FIG. 5 is an illustration of pressure plates (405, 410) applied in FIG. 4 in accordance with one embodiment of the invention. The pressure, apparatus 500 comprises pressure plates (405, 410), a top aperture 505, a bottom aperture 510, corner rods (515₁, 515₂, 515₃, 515_{N}), corner arms (520₁, 520₂, 520₃, 520_{N}), pass through holes (525₁, 525₂, 525₃, 525_{N}), and top arms (530₁, 530₂, 530₃, 530_{N}). The apertures (505, 510) are centered and formed in each pressure plate (405 and 410). The apertures (505, 510) allow the piezoelectric actuators (not shown) to be aligned when stacked between the pressure plates (405, 410). The corner rods (515₁, 515₂, 515₃, 515_{N}) are threaded and mounted to the corresponding corner arm (520₁, 520₂, 520₃, 520_{N}) of the second pressure plate 410. The pass through holes (525₁, 525₂, 525₃, 525_{N}) are mounted to the top arms (530₁, 530₂, 530₃, 530_{N}) located at corresponding corners of the first pressure plate 405, In the depicted embodiment of FIG. 4, there is a rod for each corner and corresponding through hole, however additional embodiments may have greater or fewer intersections along the perimeter of the pressure plates (405, 410), The corner rods (515 , 515₂, 515₃, 515_{N}) are inserted into the pass through holes (525₁, 525₂, 525₃, 525_{N}) to form an interference fit. in some embodiments, the corner rods (515₁, 515₂, 515₃, 515_{N}) are threaded to allow a threaded nut (not shown) to secure the rod to corresponding top arm (e.g. 530_{N}). By turning the threaded nut, pressure can be increased or decreased across the pressure plates (405, 410). In some embodiments, other shapes for the pressure apparatus 500 may be used to correspond to shape of the piezoelectric plates or for varying the pressure distribution.

FIG. 5 also depicts an embodiment where Teflon tape used as thin films 430, 450. Overlapping areas 540 and 545 protect the elastic materials 455, 425 from contamination with the adhesive during the compression. In some embodiments, films 430 and 450 can be conveniently formed with narrow Teflon/mylar or the like tapes (e.g. PTFE Thread Seal Tape).

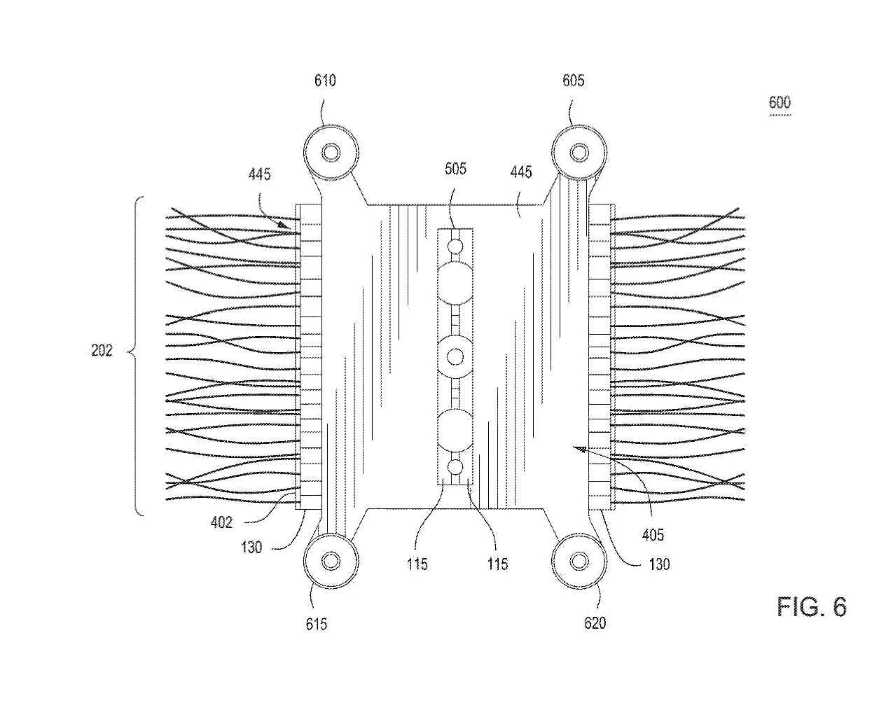

FIG. 6 is an illustration of a top view of the actuators between stacked pressure plates 600 in FIGS. 4 and 5 in accordance with one embodiment of the invention. FIG. 6 depicts eight sets of four layer piezoelectric actuators 445. Four sets are located on either side of the top aperture 505. The plates (405, 410) are secured by nuts (605, 610, 615, 620) at each corner. Wires 202 are able to be accessed along with connection points 402. The connection areas 130 and loading areas 115 are exposed for removal of adhesive excess 435, 440 and for final alignment of piezoelectric plates.

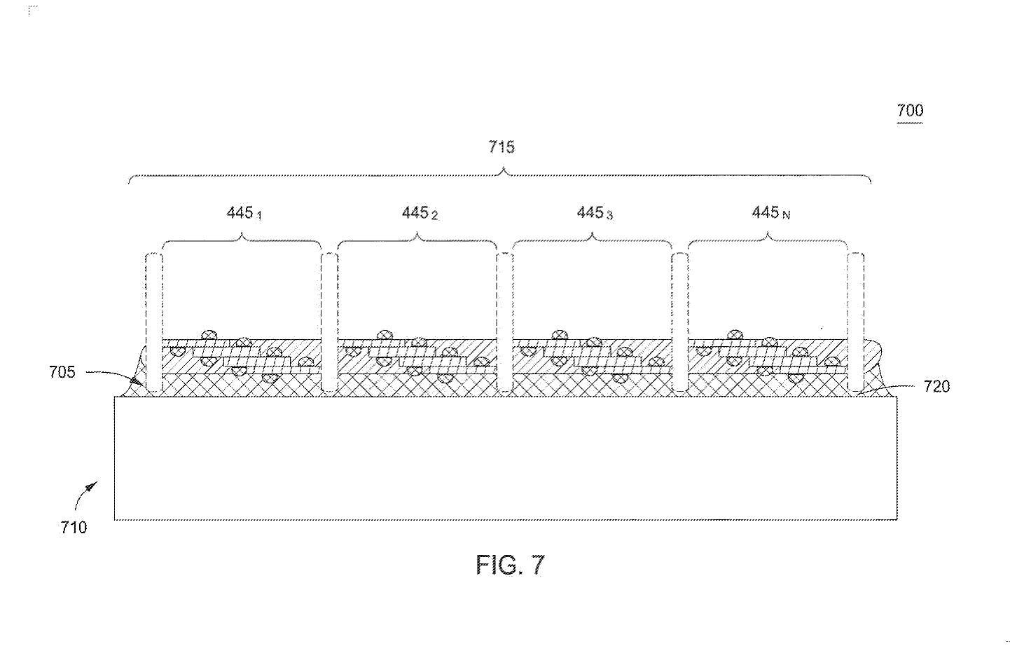

FIG. 7 is an illustration of a temporary mounting assembly 700 for final cut of the actuators (445₁, 445₂, 445₃, 445_{N}) in accordance with one embodiment of the invention. In the depicted embodiment of FIG. 7, the piezoelectric actuators (445₁, 445₂, 445₃, 445_{N}) have been released from the press 400 and disposed in a temporary adhesive 705. The temporary adhesive 705 may comprise thermoplastic or water soluble wax and secures the piezoelectric actuators (445₁, 445₂, 445₃, 445_{N}) to a support 710. The support 710 provides stability when cutting to release the piezoelectric actuators (445₁, 445₂, 445₃, 445_{N}) using for example, a diamond mill 715. The temporary adhesive 705 provides an overflow area 720 such that the diamond mill 715 may thoroughly cut below the piezoelectric actuators (445₁, 445₂, 445₃, 445_{N}). Once cutting is finished, the temporary adhesive is dissolved (e.g., by heat or chemical solution) to release the piezoelectric actuators 445 from the support 710. In some embodiments, the support 710 may be comprised of plastic, graphite or wood.

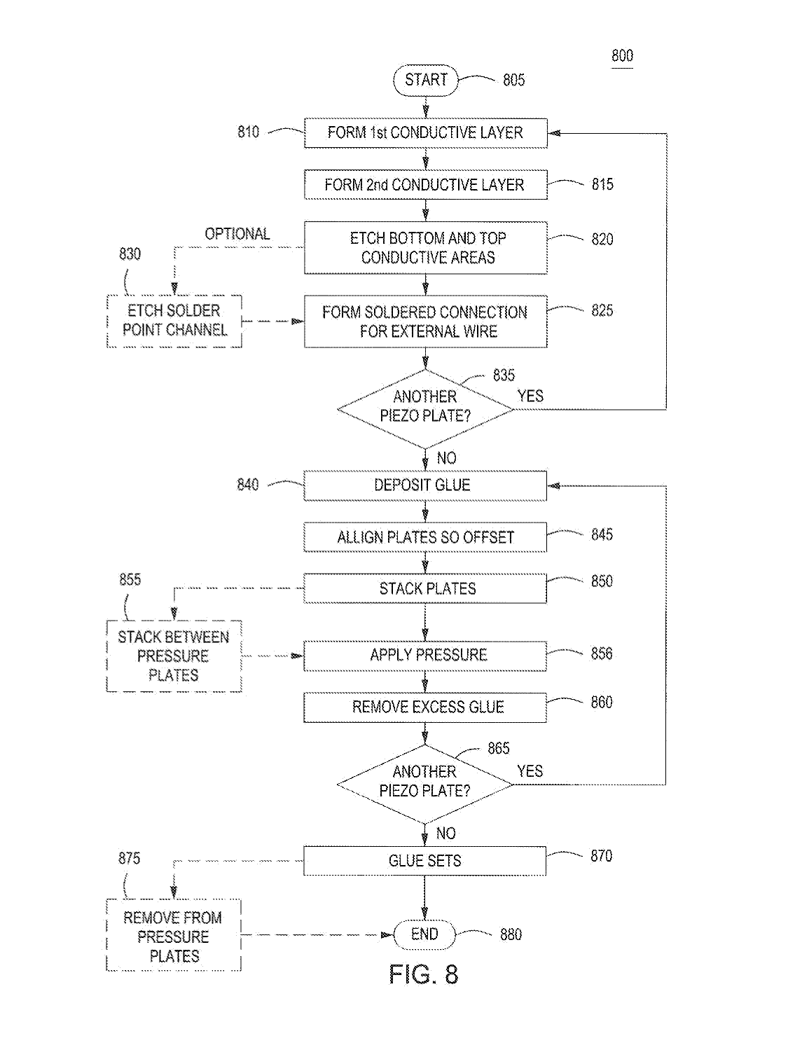

FIG. 8 is a flow diagram of an exemplary method 800 for fabricating the multilayered piezoelectric actuator in accordance with one embodiment of the invention. The method 800 begins at step 805 discloses an embodiment using glue as the adhesive agent between piezoelectric layers, however alternative embodiments may use other forms of flexible bonding such as ultrasonic welding, thermoplastic, and the like. At step 810 a first conductive layer is formed on the first piezoelectric layer (e.g. 102). Next at step 815, a second conductive layer is formed on the opposing face of the first piezoelectric layer (102). The conductive layers are etched next at step 820 to form top and bottom conductive areas comprising bending areas (120) and conductive strips (e.g., 112, 114, 117, 119) that are in non-bending areas (125, 130). Optionally, the method 800 may proceed to step 830 to etch connection point channels to increase the area of the solder junction. Continuing to step 825, wires are soldered to the conductive strips at connection points (122, 124). The method 800 at step 835 then determines whether another piezoelectric layer or plate is to be created and if true returns to step 810 to prepare the second or additional piezoelectric plate(s). Otherwise, the method 800 proceeds to step 840.

At step 840, conductive glue is applied to adhere together piezoelectric layers/plates (102, 104). Next at step 845, the plates are aligned such that the conductive bending areas (120) completely overlap and the conductive strips (e.g., 112, 114, 117, 119) are horizontally offset. The plates (102, 104) are then stacked at step 850. Optionally, the plates may be stacked between pressure plates (405, 410) at step 855. The method 800 then continues to step 856 wherein pressure is applied to the stacked plates. Step 856 produces excess glue on the sides of the pressure plates (102, 104) that is then removed at step 860.

At step 865, the method 800 determines whether another, piezoelectric plate is to be added to the stack and if true, returns to step 840. Otherwise, the method 800 continues to step 870 and allows the glue to set. If pressure plates (405, 410) were applied, the pressure plates are removed at step 875 and the method 800 ends at step 880.

In further embodiments, all piezoelectric plates may be stacked simultaneously to form the piezoelectric actuator prior to applying pressure at step 856. Further still, are embodiments where the piezoelectric actuators may need to be disposed onto a temporary mounting assembly 700 for releasing multiple actuator stacks fabricated substantially simultaneously.

While the foregoing is directed to embodiments of the present invention, other and further embodiments of the invention may be devised without departing from the basic scope thereof.

1. A layered piezoelectric actuator comprising:
a first conductive layer and second conductive layer disposed on a first piezoelectric layer;
a third conductive layer and fourth conductive layer disposed on a second piezoelectric layer;
adhesive disposed between the second conductive layer and third conductive layer, wherein the conductive layers further comprise an oscillating bending area and a stationary non-bending area, and wherein the stationary non-bending area further comprises a mount area and a connection area.

2. The actuator of claim 1, wherein the connection area further comprises at least one connection point and remains substantially stationary during periods the bending area oscillates.

3. The actuator of claim 1, wherein the second conductive layer is disposed opposite the first conductive layer on the first piezoelectric layer and the third conductive layer is disposed opposite the fourth conductive layer on the second piezoelectric layer.

4. The actuator of claim 1, wherein the first and the fourth conductive layers are coupled to a voltage source of a different polarity and second and third conductive layers are coupled to a voltage source of a same polarity.

5. The actuator of claim 1, wherein the bending area comprises a region wherein the first conductive layer and the second conductive layer directly overlap over the first piezoelectric layer and capable of inducing a voltage bias.

6. The actuator of claim 5, wherein the non-bending area comprises thinning the first and second conductive layers to form first and second continuous conductive strips.

7. The actuator of claim 6, wherein the first and second continuous conductive strips are offset such that no voltage bias may be created across the first piezoelectric layer in the non-bending area.

8. The actuator of claim 2, wherein the connection area further comprises at least one opening providing access to a connection point of a conductive layer of an adjoining piezoelectric layer.

9. The actuator of claim 5, wherein the bending areas of the first and second conductive layers directly overlap the bending areas of the third and fourth conductive layers when the first and second piezoelectric layers are stacked.

10. The actuator of claim 1, wherein when a voltage is applied, the bending areas oscillate with a frequency of up to 100 kHz and the non-bending areas remain stationary.

11. method for fabricating a layered piezoelectric. actuator comprising:
depositing a first conductive layer and second conductive layer on a first piezoelectric layer;
depositing a third conductive layer and fourth conductive layer on a second piezoelectric layer;
thinning a portion of the conductive layers to form a continuous conductive strip from each conductive layer; and
depositing adhesive between the second conductive layer and third conductive layer, wherein the conductive layers further comprise an oscillating bending area and a stationary non-bending area, and wherein the stationary non-bending area further comprises a mount area, and a connection area.

12. The method of claim 11, wherein the connection area further comprises at least one connection point and remains substantially stationary during periods the bending area oscillates.

13. The method of claim 11, further comprising stacking the bending area such that the first conductive layer and the second conductive layer directly overlap over the first piezoelectric layer and capable of inducing a voltage bias.

14. The method of claim 11, wherein the first and second continuous conductive strips are offset such that no voltage bias may be created across the first piezoelectric layer.

15. The method of claim 11, further comprising forming a wire connection point at the distal end of the conductive strips for coupling external wires.

16. The method of claim 15, further comprising etching a channel in the piezoelectric layers of the wire connection point for solder.

17. The method of claim 11, further comprising stacking the piezoelectric layers between pressure plates and wherein the adhesive is liquid adhesive.

18. The method of claim 17, where pressure plates further comprise flexible films to protect the pressure plates from squeezed liquid adhesive.

19. The method of claim 18, further comprising increasing the pressure of the pressure plates to squeeze out excess liquid adhesive wherein the liquid adhesive excess fills the opening and covers the wire connection point, thereby providing the mechanical and electrical protection of a distal wire connection point end.

20. The method of claim 11, wherein when a voltage is applied, the bending areas oscillate with at least a frequency of 1 kHz and the non-bending areas remain stationary.
